(19) United States
(12) Patent Application Publication
(10) Pub. No.: US 2012/0219724 A1
(43) Pub. Date: Aug. 30, 2012

(54) METHOD FOR FORMING METAL OXIDE FILM, METHOD FOR FORMING MANGANESE OXIDE FILM, AND COMPUTER-READABLE STORAGE MEDIUM

(75) Inventors: Koji Neishi, Nirasaki-shi (JP); Junichi Koike, Sendai-shi (JP); Kenji Matsumoto, Nirasaki-shi (JP)

(73) Assignees: TOHOKU UNIVERSITY, Miyagi (JP); TOKYO ELECTRON LIMITED, Tokyo (JP)

(21) Appl. No.: 13/497,929

(22) PCT Filed: Sep. 17, 2010
(86) PCT No.: PCT/JP2010/066228

§ 371 Date: May 14, 2012

(30) Foreign Application Priority Data
Sep. 24, 2009 (JP) 2009-219283

(51) Int. Cl. C23C 16/18; C23C 16/52; C23C 16/50

(52) U.S. Cl. 427/539; 427/255.28; 118/697; 427/248.1

(57) ABSTRACT

In a method for forming a metal oxide film, by which excellent adhesion between the film and Cu can be provided, a gas containing an organometallic compound is supplied to a base, and the metal oxide film is formed on the base. After forming the metal oxide film on the base by supplying the organometallic compound to the base, the metal oxide film is exposed to the oxygen-containing gas or oxygen-containing plasma in the final step of the process of forming the metal oxide film.

### FIELD OF THE INVENTION

The present invention relates to a method for forming a metal oxide film, a method for forming a manganese oxide film, and a computer-readable storage medium therefor.

### BACKGROUND OF THE INVENTION

With an increase of an integration density of a semiconductor device, a geometric dimension of the semiconductor device or an internal wiring thereof is getting smaller. A resistance of the internal wiring, e.g., Cu wiring, increases as the geometric dimension of the Cu wiring is decreased. In order to suppress an increase of a resistance, a resultant resistance of the barrier layer and the Cu wiring needs to be reduced by decreasing a thickness of a diffusion barrier film (hereinafter, referred to as a “barrier layer”) for preventing diffusion of Cu.

The barrier layer is formed by physical vapor deposition (PVD) (sputtering), as described in Japanese Patent Application Publication No. 2008-28046.

However, in the thin barrier layer formed by PVD, if the geometric dimension of the Cu wiring is decreased to, e.g., about 45 nm or below, a step coverage of a recess for burying the Cu wiring starts to deteriorate. Therefore, it is not desirable to form a thin film layer by PVD.

On the other hand, attention has been drawn to chemical vapor deposition (CVD) used for forming a barrier layer since it provides a better step coverage for a recess, compared to PVD. Especially, the present inventors have found that a manganese oxide film formed by CVD has an excellent step coverage for a fine recess even when its thickness is small. The manganese oxide film formed by CVD is one of strong candidates for a new barrier layer material.

The present inventors have also found that the adhesivity between Cu and the manganese oxide film formed by CVD depends on the content of carbon (C) in the manganese oxide film. In other words, when the content of C in the manganese oxide film is high, the adhesivity between Cu and the manganese oxide film is decreased.

### SUMMARY OF THE INVENTION

In view of the above, the present invention provides a metal oxide film forming method and a manganese oxide film forming method, capable of providing excellent adhesion with Cu, and a computer-readable storing medium for storing therein a program for performing the film forming methods by using a film forming apparatus.

In accordance with a first aspect of the present invention, there is provided a method for forming a metal oxide film on a base by supplying a gas containing an organometallic compound to the base, including forming the metal oxide film on the base by supplying the gas containing an organometallic compound to the base; and exposing the metal oxide film to an oxygen-containing gas or an oxygen-containing plasma in a final step of the process of forming the metal oxide film.

In accordance with a second aspect of the present invention, there is provided a method for forming a manganese oxide film on a base by supplying a gas containing an organomanganese compound to the base, including forming the manganese oxide film on the base by supplying the gas containing an organometallic compound to the base; and exposing the manganese oxide film to an oxygen-containing gas or an oxygen-containing plasma in a final step of the process of forming the manganese oxide film.

In accordance with a third aspect of the present invention, there is provided a computer-readable storage medium storing a control program for controlling a film forming apparatus, wherein the control program controls, when executed, the film forming apparatus to execute the metal oxide film forming method in accordance with the first or second aspect.

### BRIEF DESCRIPTION OF THE DRAWINGS

FIG. 1 is a cross sectional view schematically showing an example of a film forming apparatus capable of performing a manganese oxide film forming method in accordance with an embodiment of the present invention.

FIG. 2 shows a CIsXPS spectrum of a manganese oxide film.

FIG. 3 is a timing diagram showing an example of a sequence of the manganese oxide film forming method.

FIGS. 4A to 4E are cross sectional views showing an example of the manganese oxide film forming method.

FIG. 5 shows a state in which an unreacted organomanganese compound reacts completely.

FIG. 6 shows a structural formula of (EtCp)₂Mn.

FIGS. 7A and 7B show a result obtained by performing a secondary ion mass spectrometry analysis on a structure in which a plasma TEOS film, a manganese oxide film and a copper film are stacked in a depth direction thereof.

FIG. 8 is a timing diagram showing another example of the sequence of the manganese oxide film forming method.

FIG. 9 is a timing diagram showing still another example of the sequence of the manganese oxide film forming method.

FIG. 10 shows a result obtained by analyzing a surface binding state of a manganese oxide film by a Raman spectroscopy.

### DETAILED DESCRIPTION OF THE EMBODIMENTS

Hereinafter, an embodiment of the present invention will be described with reference to the accompanying drawings which form a part hereof. Throughout the entire drawings, like reference numerals denote like parts.

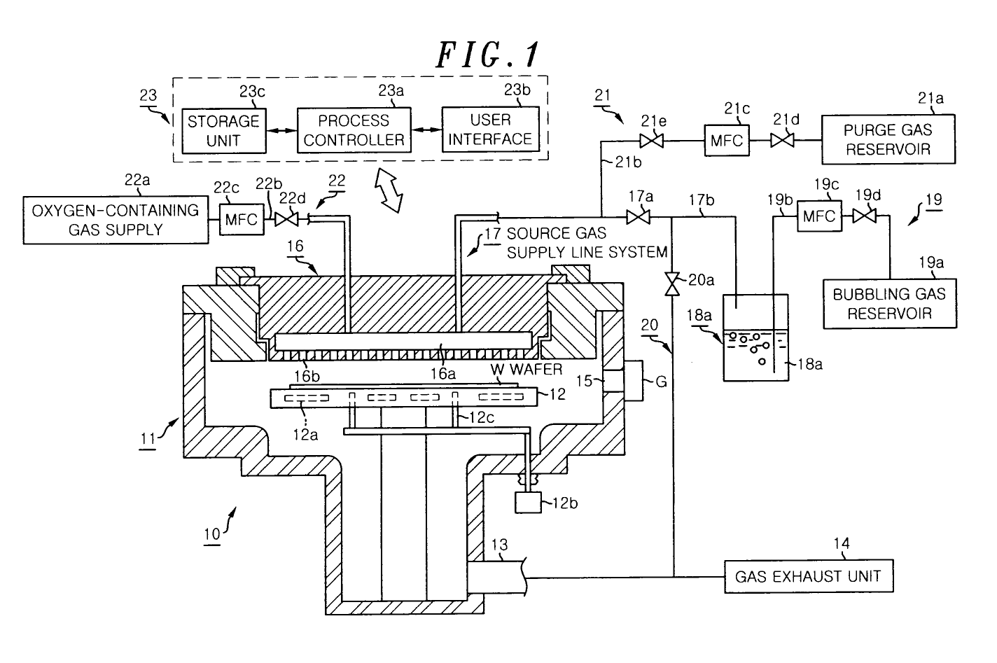

FIG. 1 is a cross sectional view schematically showing an example of a film forming apparatus capable of performing a metal oxide film forming method, e.g., a manganese oxide film forming method in accordance with an embodiment of the present invention. In this embodiment, a thermal CVD apparatus for forming a manganese oxide film on a target substrate, e.g., a semiconductor wafer (hereinafter, referred to as a “wafer”), to be processed is described as an example of a film forming apparatus. However, the metal oxide film is not limited to the manganese oxide film, and the target substrate is not limited to the semiconductor wafer. The film forming apparatus is not limited to the thermal CVD apparatus.

As shown in FIG. 1, a thermal CVD apparatus 10 includes a processing chamber 11. A mounting table 12 for horizontally mounting a wafer W thereon is provided in the processing chamber 11. A heater 12a serving as a temperature control unit is embedded in the mounting table 12. A temperature measurement unit (not shown), e.g., a thermocouple, is attached to the heater 12a in order to control a temperature. The mounting table 12 is provided with three lifter pins 12c (only two are shown for convenience) that can be moved up and down by an elevation mechanism 12b. The wafer W is moved up and down by the lifter pines 12c and transferred between a wafer transfer unit (not shown) and the mounting table 12.

A gas exhaust line 14 has one end connected to a bottom portion of the processing chamber 11 and the other end connected to a gas exhaust unit 14. A transfer port 15 is formed at a sidewall of the processing chamber 11. The transfer port 15 can be opened and closed by a gate valve G.

A gas shower head 16 is provided at a ceiling portion of the processing chamber 11 to face the mounting table 12. The gas shower head 16 has a gas chamber 16a. A gas introduced into the gas chamber 16a is supplied into the processing chamber 11 through a plurality of gas injection holes 16b.

The gas shower head 16 is connected to a source gas supply line system 17 for introducing a source gas, e.g., a gas containing an organomanganese compound, into the gas chamber 16a.

The source gas supply line system 17 has a source gas supply line 17a. A source material reservoir 18 is connected to an upstream side of the source gas supply line 17a. A manganese source material, e.g., an organomanganese compound, is stored in the source material reservoir 18. In this embodiment, a cyclopentadienyl-based organomanganese compound, e.g., (EtCp)₂Mn(bis(ethylcyclopentadienyl)manganese) 18a, is stored in a liquid state as an organomanganese compound. EtCp)₂Mn is a manganese precursor. The source material reservoir 18 is connected to a bubbler 19.

The bubbler 19 includes, e.g., a bubbling gas reservoir 19a for storing a bubbling gas therein; a bubbling gas supply line 19b through which the bubbling gas is supplied to the source material reservoir 18; a mass flow controller 19c (MFC) for controlling a flow rate of the bubbling gas flowing through the bubbling gas supply line 19b; and a valve 19d. The bubbling gas may be, e.g., argon (Ar) gas, hydrogen (H₂) gas and a nitrogen (N₂) gas or the like. One end of the bubbling gas supply line 19b is submerged in a source material liquid, i.e., (EtCp)₂Mn in this embodiment, stored in the source material reservoir 18. By injecting the bubbling gas from the bubbling gas supply line 19b, the source material liquid is bubbled and vaporized. Thee vaporized source gas, i.e., vaporized (EtCp)₂Mn in this embodiment, is introduced into the processing chamber 16a through the gas supply line 17a and the valve 17b for opening and closing the source gas supply line 302.

A method for supplying the source gas is not limited to the above-described bubbling method for bubbling and vaporizing the source liquid, and there may be employed a so-called liquid transport method for transporting a source liquid to a vaporizer and vaporizing the source liquid by the vaporizer.

A pre-flow line 20 connected to the gas exhaust unit 14 is disposed between the valve 17b and the source material reservoir 18. The pre-flow line 20 is provided with a valve 20a. Until the bubbling flow rate of the source gas is stabilized, the source gas flows through the pre-flow line 20 by closing the valve 17b and opening the valve 20a. When the bubbling flow rate is stabilized and the supply timing of the source gas has come, the source gas is controlled to flow through the source gas supply line 17a by closing the valve 20a and opening the valve 17b.

A purge mechanism 21 is connected between the valve 17b and the gas chamber 16a.

The purge mechanism 21 includes, e.g., a purge gas reservoir 21a for storing a purge gas therein; a purge gas supply line 21b through which the purge gas is flowed to the source gas supply line 17a; a mass flow controller (MFC) 21c for controlling a flow rate of the purge gas flowing through the purge gas supply line 21b; and valves 21d and 21e. The valve 21d is provided between the purge gas reservoir 21a and the mass flow controller 21c, and the valve 21e is provided between the source gas supply line 17a and the mass flow controller 21c. The purge gas may be, e.g., a rare gas such as Argon (Ar) gas or the like, hydrogen (H₂) gas, and nitrogen (N₂) gas or the like.

When the interiors of the source gas supply line 17a, the gas chamber 16a, and the processing chamber 11 are purged, the purge gas is supplied into the source gas supply line 17a through the purge gas supply line 21b by closing the valve 17b and opening the valves 21d and 21e. The purge gas may also be used as a bubbling gas for the source gas. In other words, the bubbling gas reservoir 19a and the purge gas reservoir 21a may have the same configuration.

An oxygen-containing gas supply line system 22 for introducing an oxygen-containing gas into the gas chamber 16a is connected to the gas shower head 16.

The oxygen-containing gas supply line system 22 includes an oxygen-containing gas generator 22a for generating an oxygen-containing gas; an oxygen-containing gas supply line 22b; a mass flow controller (MFC) 22c for controlling a flow rate of an oxygen-containing gas flowing through the oxygen-containing gas supply line 22b; and a valve 22d. The oxygen-containing gas may be, e.g., water (H₂O), oxygen (O₂) or the like.

The oxygen-containing gas is introduced into the gas chamber 16a through the oxygen-containing gas supply line 22b by opening the valve 22d. The oxygen-containing gas introduced into the gas chamber 16a is injected through the gas injection holes 16b and supplied to the processing chamber 11. The source gas supply line 17a, the valve 19d, the gas shower head 16, and the sidewall of the chamber 11 are heated to, e.g., about 80° C., by a heater (not shown) in order to prevent condensation of the source gas.

The control unit 23 controls the thermal CVD apparatus 10. The control unit 23 includes a process controller 23a, a user interface 23b, and a storage unit 23c. The user interface 23b includes a keyboard through which a process manager inputs commands for managing the thermal CVD apparatus 10; a display for visually displaying an operation state of the thermal CVD apparatus 10; and the like. The storage unit 23C stores therein recipes such as operating condition data or control programs to be used in realizing processes performed by the thermal CVD apparatus 10 under the control of the process controller 23a.

If necessary, the recipes are read out from the storage unit 23c under the instruction from the user interface 23b and executed by the process controller 23a, thereby controlling the thermal CVD apparatus 10. The recipes may be stored in a computer-readable storage medium such as a CD-ROM, a hard disk, a flash memory or the like. Besides, the recipes may be transmitted from other devices via, e.g., a dedicated line, whenever necessary.

In accordance with the thermal CVD apparatus 10, a manganese oxide film can be formed on a surface of a wafer W by supplying to the surface of the wafer W a source gas, e.g., a cyclopentadienyl-based organomanganese compound such as (EtCp)₂Mn gas.

As for the cyclopentadienyl-based organomanganese compound gas, any one of the following cyclopentadienyl-based organomanganese compounds as well as (EtCp)₂Mn[═Mn(C₂H₅C₅H₄)₂] may be used.

Cp₂Mn[═Mn(C₅H₅)₂]

(MeCp)₂Mn[═Mn(CH₃C₅H₄)₂]

(i-PrCp)₂Mn[═Mn(C₃H₇C₅H₄)₂]

MeCpMn(CO)₃[═(CH₃C₅H₄)Mn(CO)₃]

(t-BuCp)₂Mn[═Mn(C₄H₉C₅H₄)₂]

Mn(DMPD)(EtCp)[=Mn (C₇H₁₁C₂H₅C₅H₄)]

((CH₃)₅Cp)₂Mn[═Mn((CH₃)₅C₅H₄)₂]

Hereinafter, an example of a manganese oxide film forming method in accordance with the embodiment of the present invention will be described.

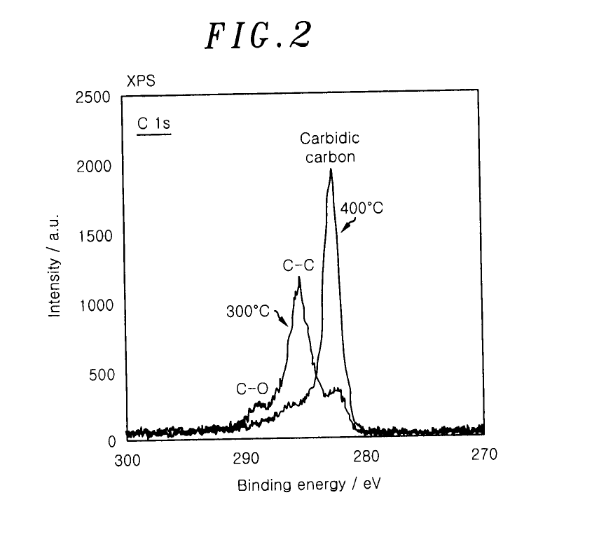

A large amount of carbon C is contained in the manganese oxide film formed by using the organomanganese compound gas, which is, e.g., a cyclopentadienyl-based organomanganese compound gas such as (EtCp)₂Mn gas. This will be described by using an X-ray photoelectron spectroscopy (XPS). FIG. 2 shows an analysis result of a chemical binding state of a CIs (carbon) peak. In FIG. 2, there are illustrated a C1sXPS spectrum (400° C.) of a manganese oxide film formed at a temperature of about 400° C. and a C1sXPS spectrum (300° C.) of a manganese oxide film formed at a temperature of about 300° C.

As shown in FIG. 2, large peaks of C—C and C—O are observed in case of the manganese oxide film formed at the temperature of about 300° C., and a peak of carbidic carbon is mainly observed in case of the manganese oxide film formed at the temperature of about 400° C.

The above results show that, when a manganese oxide film is formed by using an organomanganese compound gas, e.g., a cyclopentadienyl-based organomanganese compound gas ((EtCp)₂Mn gas in the present embodiment), a large amount of carbon (c) is contained in the formed manganese oxide film.

If the manganese oxide film contains a large amount of C, the adhesivity between the manganese oxide film and Cu or Cu alloy formed on the manganese oxide film is deteriorated. Therefore, it is preferable to minimize the concentration of C in the manganese oxide film. In the present embodiment, a manganese oxide film was formed by the following manner in order to minimize the concentration of C in the manganese oxide film.

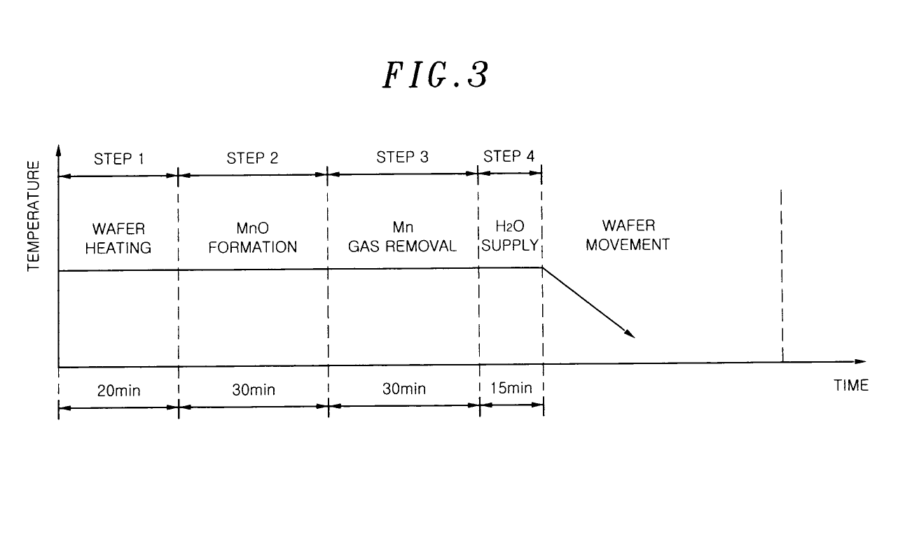

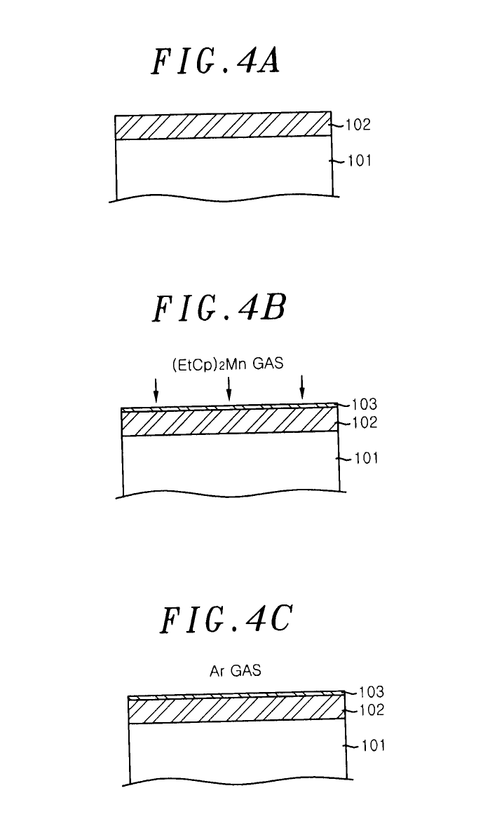

FIG. 3 is a timing diagram showing a sequence of an example of a manganese oxide film forming method in accordance with the embodiment of the present invention. FIGS. 4A to 4E are cross sectional views showing main processes of an example of the manganese oxide film forming method in accordance with the embodiment of the present invention.

First, as shown in FIGS. 3 and 4A, a plasma tetraethylorthosilicate (TEOS) film (silicon oxide film) 102 having a thickness of about 100 nm is formed on a p-type silicon wafer 101 serving as a substrate. Then, the wafer 101 having the plasma TEOS film 102 thereon is transferred to the processing chamber 11 of the film forming apparatus 10 shown in FIG. 1 and mounted on the mounting table 12. Thereafter, the wafer 101 is heated by the heater 12a to a temperature in a range from about 100° C. to about 400° C., for example, (step 1 in FIG. 3). The heating time is, e.g., about 20 min.

Next, as shown in FIGS. 3 and 4B, an organomanganese compound, e.g., a cyclopentadienyl-based organomanganese compound ((EtCp)₂Mn in the present embodiment), is vaporized at a temperature of about 80° C. while using H₂ gas as a bubbling gas (to become carrier gas), so that (EtCp)₂Mn gas is produced. Then, the organomanganese compound gas is introduced into the processing chamber 11 together with a carrier gas, and the (EtCp)₂Mn gas is supplied onto the surface of the plasma TEOS film 102 (step 2 in FIG. 3). The film forming time is, e.g., about 30 min. In this step, (Etcp)₂Mn reacts with oxygen or moisture remaining in the plasma TEOS film 102. Accordingly, a manganese oxide film 103 is formed on the plasma TEOS film 102. At this time, the oxidation state of the formed manganese oxide film 103 is MnO.

Next, as shown in FIGS. 3 and 4C, a purge gas is introduced into the processing chamber 11 while stopping the supply of the (EtCp)₂Mn gas, so that the (EtCp)₂Mn gas is removed from the processing chamber 11 (step 3). In the present embodiment, Ar gas is used as the purge gas and supplied into the processing chamber 11 at a flow rate of about 25 sccm while vacuum-evacuating the processing chamber 11 by using the gas exhaust unit 14. The supply time is e.g., about 30 min.

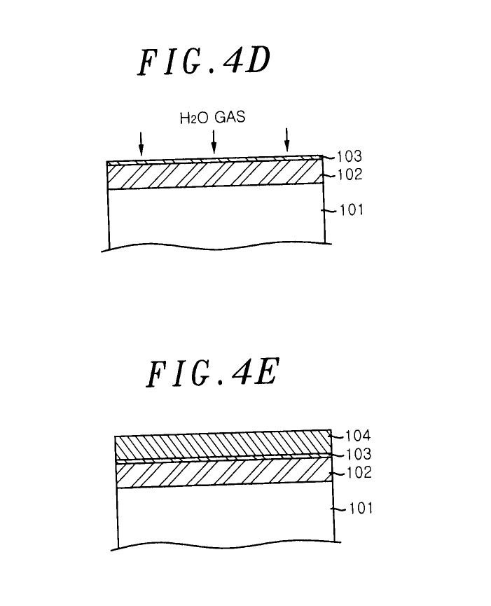

Then, as shown in FIGS. 3 and 4D, an oxygen-containing gas is introduced into the processing chamber 11 while stopping the supply of Ar gas, and the oxygen-containing gas is supplied onto the surface of the manganese oxide film 103 (step 4 in FIG. 3). In the present embodiment, steam (H₂O) as the oxygen-containing gas is supplied into the processing chamber 11 at a flow rate of about 1 sccm while closing a gas exhaust system valve (not shown). The supply time is, e.g., about 15 min. Hence, (EtCp)₂Mn, for example, which remains in an unreacted state on the manganese oxide film 103 completely reacts with H₂O, thereby becoming manganese oxide (MnO). This state is shown in FIG. 5. FIG. 5 shows a state in which OH-group is bonded to a dangling bond generated by detachment of a ligand (ethylcyclopentadienyl (EtCp) in the present embodiment) from the unreacted (EtCp)₂Mn and the surface of the manganese oxide film 103 is terminated with the OH-group. Further, hydrocarbon (C—H) contained in the ligand is vaporized and then exhausted.

The supply amount of the oxygen-containing gas, i.e., the supply amount of H₂O in the present embodiment, is preferably set such that the organomanganese compound serving as a manganese precursor which remains on the surface of the manganese oxide film 103 and inside the processing chamber 11 can react therewith without excess and deficiency. An example of the amount capable of achieving the reaction without excess and deficiency is described as follows.

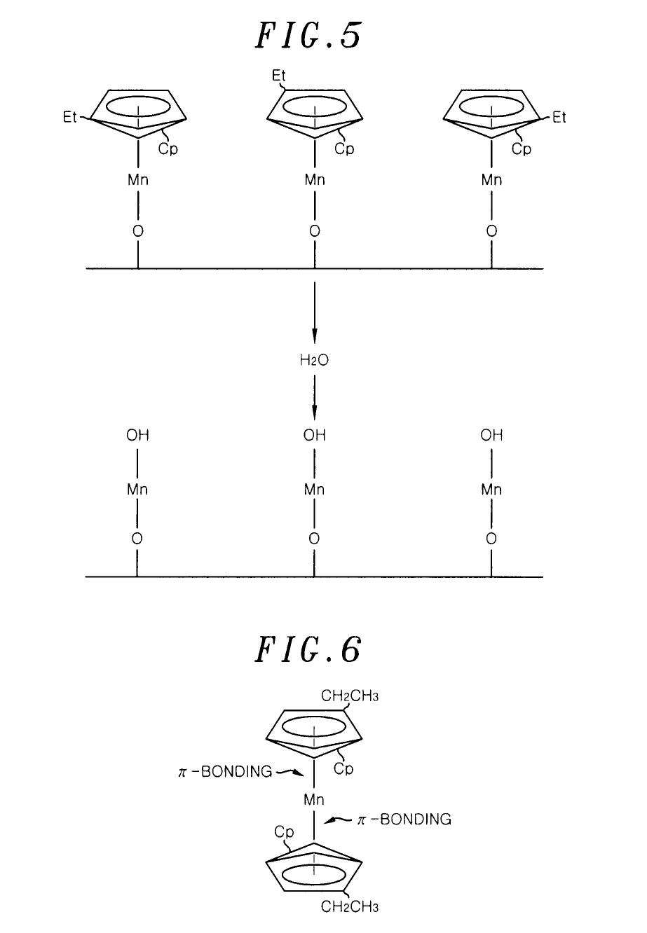

In the present embodiment, an organomanganese compound serving as the manganese precursor is a cyclopentadienyl-based organomanganese compound. FIG. 6 shows a basic structural formula of a cyclopentadienyl-based organomanganese compound. FIG. 6 shows a basic structural formula of (EtCp)₂Mn. As shown in FIG. 6, (EtCp)₂Mn has a structure in which Mn is n-bonded to two ligands (EtCp). In order to allow the organomanganese compound to react without excess and deficiency, the amount of the oxygen-containing gas is set such that the chemical reaction between Mn and the ligands of the organomanganese compound, i.e., n-bond between Mn and (EtCp) in the example shown in FIG. 6, is cut and Mn is exposed. In the present embodiment, the ligand is a five-membered ring, and the five-membered ring ligand is Cp(cyclopentadienyl).

For example, the supply amount of the oxygen-containing gas which allows the organomanganese compound to react therewith without excess and deficiency may be smaller than or equal to the supply amount of the organomanganese compound. For example, when the remaining organomanganese compound completely reacts with the oxygen-containing gas, e.g., H₂O, the following reaction scheme is obtained.

(EtCp)₂Mn+H₂O→MnO+2H(EtCp)

In the above reaction scheme, even if the supply amount of H₂O is larger than the supply amount of the organomanganese compound, it does not contribute to the reaction. Further, most of the organomanganese compound is used for the MnO film formation reaction or exhausted without contributing to the film formation reaction, so that the amount of the organic compound remaining in the manganese oxide film 103 is remarkably smaller than the supply amount of the organomanganese compound.

Therefore, in order to allow the remaining organomanganese compound to react without excess and deficiency, it is preferable to set the supply amount of H₂O to be smaller than or equal to that of the organomanganese compound. For example, when the film formation is performed by supplying (EtCp)₂Mn at a flow rate of about 4 sccm for 10 min, the total supply amount of the organomanganese compound is about 40 cc. In that case, the maximum supply amount of H₂O is about 40 cc. Specifically, when the supply time of H₂O is about 1 min, the flow rate of H₂O is preferably about 40 sccm or below. Moreover, when the supply time of H₂O is about 10 min, the flow rate of H₂O is preferably about 4 sccm or below.

A partial pressure of the oxygen-containing gas in the processing chamber 11 at the time of supplying the oxygen-containing gas is preferably set in a range from about 1 ppb to about 10 ppm. Especially, the partial pressure of the oxygen-containing gas is more preferably set to be about 0.1 ppm.

Then, as shown in FIGS. 3 and 4E, the wafer 101 having the manganese oxide film 103 thereon is unloaded from the processing chamber 11 and transferred to, e.g., a copper film forming apparatus, without breaking vacuum or bringing the manganese oxide film into contact with oxygen or the air, to thereby form, e.g., a Cu film 104 on the manganese oxide film.

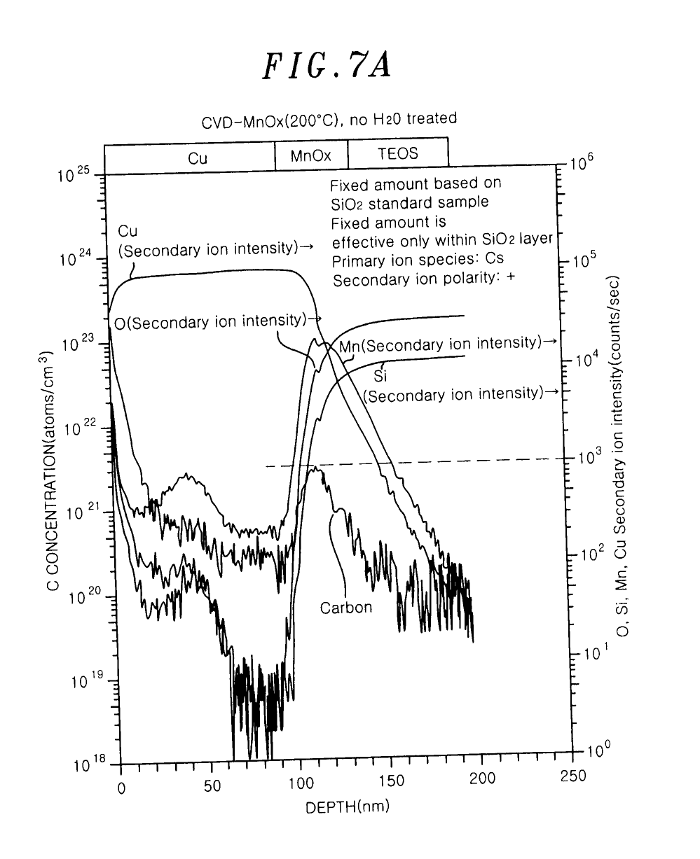

FIGS. 7A and 7B show a result obtained by performing a secondary ion mass spectrometry analysis in a depth direction of a structure in which the TEOS film 102, the manganese oxide film 103 and the copper film 104 shown in FIG. 4E are stacked. FIG. 7A shows the case in which H₂O is not supplied to the manganese oxide film 103, and FIG. 7B shows the case in which H₂O is supplied to the manganese oxide film 103.

As shown in FIG. 7A, when H₂O is not supplied to the manganese oxide film 103, the concentration of C in the manganese oxide film 103 was about 3×10²¹ to 4×10²¹ atoms/cm³. On the other hand, as shown in FIG. 7B, when H₂O is supplied to the manganese oxide film 103, the concentration of C in the manganese oxide film 103 was reduced to about 1.5×10²¹ atoms/cm³.

As such, in the manganese oxide film forming method of the present embodiment, the manganese oxide film 103 is formed and, then, an oxygen-containing gas is supplied to the formed manganese oxide film 103. Accordingly, even when the organomanganese compound serving as the manganese precursor remains in an unreacted state on the surface of the manganese oxide film 103, the remaining organomanganese compound can react completely. In accordance with the present embodiment, it is possible to obtain a manganese oxide film forming method capable of minimizing the content of C in a manganese oxide film and providing excellent adhesion between the film and Cu.

Meanwhile, when an oxygen-containing gas is supplied to the previously formed manganese oxide film 103, the manganese oxide film 103 may be oxidized. Since, however, the oxidation sate of the manganese oxide film 103 formed in accordance with the above-described embodiment is MnO, even if H₂O is supplied to the formed manganese oxide film, the oxidation state of the manganese oxide film is not changed to MnO₂ in view of thermodynamic consideration.

While the invention has been shown and described with respect to the embodiment, the present invention can be variously changed and modified without departing from the scope of the invention. Further, an embodiment of the present invention is not limited to the above-described embodiment.

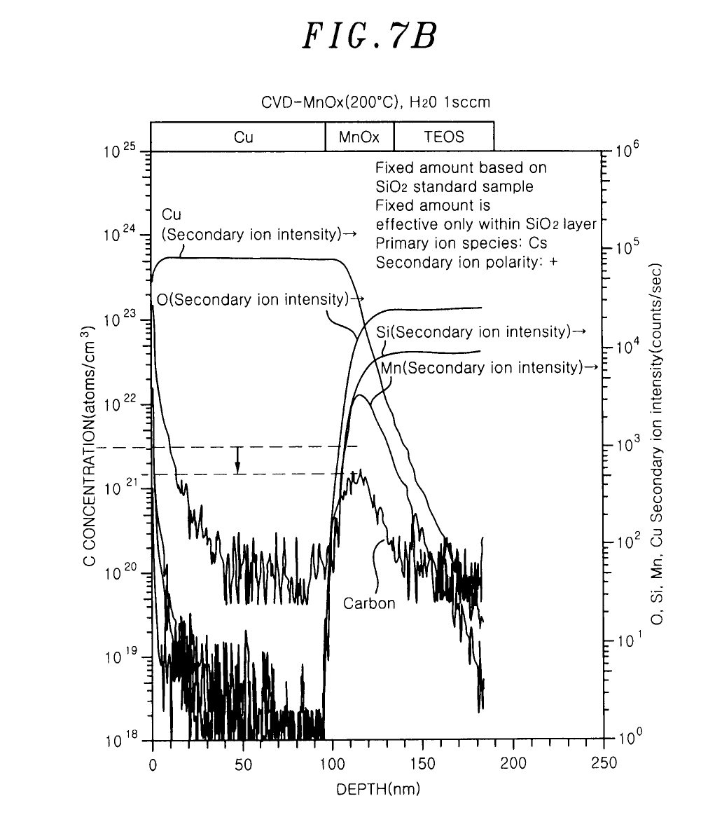

For example, in the above embodiment, a process (step 3 in FIG. 3) of removing the organomanganese compound gas from the processing chamber 11 is separately performed after the process of forming the manganese oxide film by using the organomanganese compound gas as a source gas. However, it is not necessary to remove the organomanganese compound gas form the processing chamber 11. For example, as shown in FIG. 8, an oxygen-containing gas (water) may be supplied while stopping the supply of the organomanganese compound (Mn precursor).

In brief, a process recipe completes the film forming process after the supply of the oxygen-containing gas without supplying the organomanganese compound. By supplying the oxygen-containing gas in the final step of the film forming process, ligands containing C are separated from the surface of the manganese oxide film, thereby resulting in a more perfect MnO film. Upon completion of this process recipe, Cu or Cu alloy is formed on the manganese oxide film 103 without breaking vacuum or bringing the manganese oxide film 103 into contact with oxygen, water or the air.

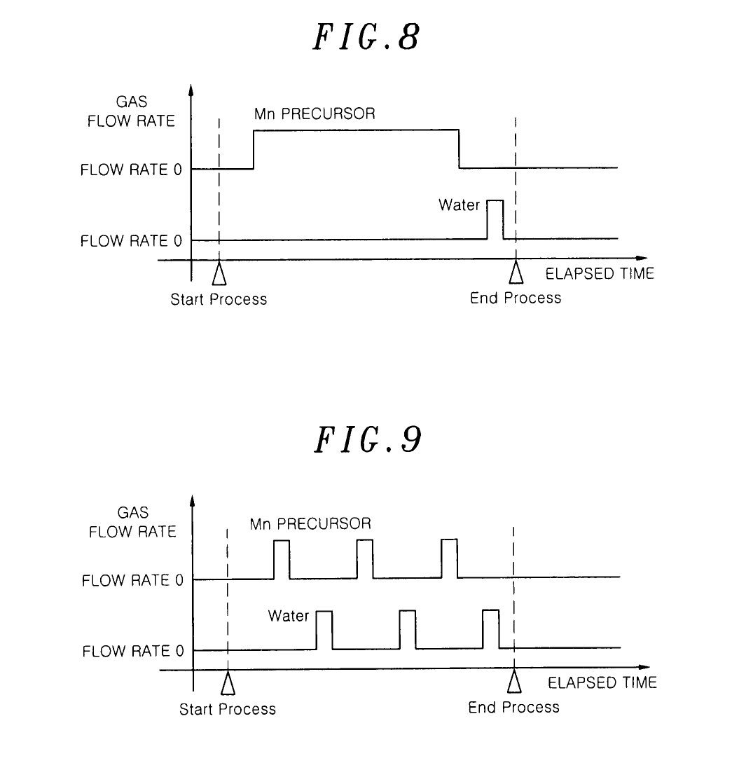

Although chemical vapor deposition (CVD), especially thermal CVD, has been described in the above embodiment, the film forming method is not limited to the CVD. For example, as shown in FIG. 9, atomic layer deposition (ALD) for forming a manganese oxide film in an atom layer level or a molecule layer level by alternately supplying a source gas, e.g., an organomanganese compound (Mn precursor) gas, and an oxygen-containing gas (water) may be used. Even in the case of using the ALD method, the process recipe completes the film forming process after the supply of an oxygen-containing gas without supplying an organomanganese compound gas. Upon completion of this process recipe, Cu or Cu alloy is formed on the manganese oxide film 103 without breaking vacuum or brining the manganese oxide film 103 into contact with oxygen, water or the air.

In the present embodiment, in a process of removing C from the manganese oxide film 103, an oxygen-containing gas, e.g., H₂O, is supplied to the manganese oxide film 103 and the manganese oxide film 103 is exposed to H₂O. However, the manganese oxide film 103 may be exposed to an oxygen-containing plasma instead of H₂O.

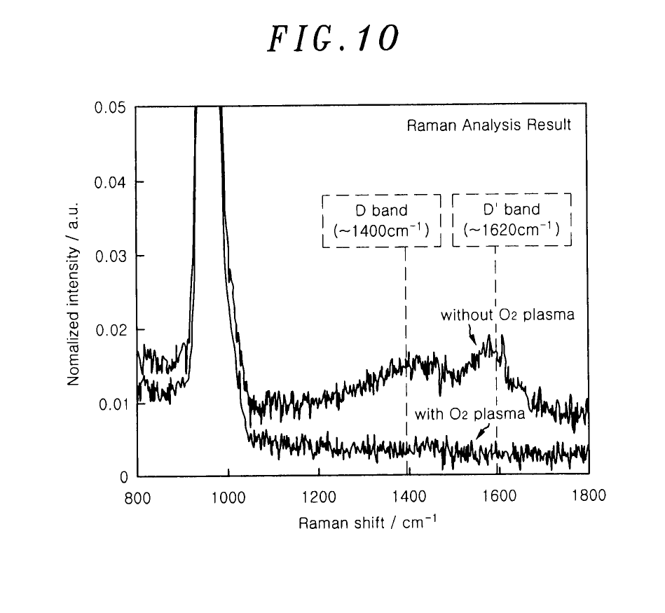

FIG. 10 shows a result obtained by analyzing a surface binding state of the manganese oxide film 103 by a Raman spectroscopy in the cases of exposing and not exposing the manganese oxide film 103 to O₂.

FIG. 10 shows a Raman spectroscopy result of the manganese oxide film 103 that is formed at a film forming temperature of about 400° C. for about 30 min while supplying a carrier gas, e.g., H₂ gas, at a flow rate of about 25 sccm. In that case, an O₂ plasma processing was performed for about 10 sec by a parallel plate type plasma processing apparatus while supplying O₂ gas at a flow rate of about 2 sccm and applying a high frequency power of about 40 kHz at 100 W.

As can be seen by Raman spectra illustrated in FIG. 10, when the manganese oxide film 103 is not exposed to an O₂ plasma (without O₂ plasma), notable peaks (D band and D′ band) originating from carbon (including amorphous carbon) are observed.

On the contrary, when the manganese oxide film 103 is exposed to an O₂ plasma (with O₂ plasma), no notable peak originating from carbon is not observed.

As such, even when the manganese oxide film 103 is exposed to an oxygen(O₂)-containing plasma, instead of an oxygen-containing gas, e.g., H₂O, the concentration of C in the manganese oxide film 103 can be reduced, and the manganese oxide film having excellent adhesivity to Cu can b obtained.

In addition, the present invention can be variously modified without departing from the scope of the present invention.

In accordance with the present invention, it is possible to provide a metal oxide film forming method capable of providing excellent adhesion between the film and Cu, a manganese oxide film forming method, and a computer-readable storage medium for storing a program for performing the film forming methods by using a film forming apparatus.

What is claimed is:

1. A method for forming a metal oxide film on a base by supplying a gas containing an organometallic compound to the base, comprising:
forming the metal oxide film on the base by supplying the gas containing an organometallic compound to the base; and
exposing the metal oxide film to an oxygen-containing gas or an oxygen-containing plasma in a final step of the process of forming the metal oxide film.

2. A method for forming a manganese oxide film on a base by supplying a gas containing an organomanganese compound to the base, comprising:
forming the manganese oxide film on the base by supplying the gas containing an organometallic compound to the base; and
exposing the manganese oxide film to an oxygen-containing gas or an oxygen-containing plasma in a final step of the process of forming the manganese oxide film.

3. The method of claim 2, wherein the oxygen-containing gas is steam (H₂O) or oxygen (O₂).

4. The method of claim 2, wherein the organomanganese compound has a structure in which Mn and ligand are n-bonded.

5. The method of claim 4, wherein the ligand is a five-membered ring.

6. The method of claim 5, wherein the five-membered ring ligand is Cp(cyclopentadienyl).

7. The method of claim 6, wherein the organomanganese compound is selected from the group consisting of:
(EtCp)₂Mn[═Mn(C₂H₅C₅H₄)₂];
Cp₂Mn[═Mn(C₅H₅)₂];
(MeCp)₂Mn[═Mn(CH₃C₅H₄)₂];
(i-PrCp₂Mn[═Mn(C₃H₇C₅H₄)₂];
MeCpMn(CO)₃[═(CH₃C₅H₄)Mn(CO)₃];
(t-BuCp)₂Mn[═Mn(C₄H₉C₅H₄)₂];
Mn(DMPD)(EtCp)[=Mn(C₇H₁₁C₂H₅C₅H₄)]; and
((CH₃)₅Cp)₂Mn[═Mn((CH₃)₅C₅H₄)₂].

8. The method of claim 4, wherein a supply amount of the oxygen-containing gas is set such that the manganese oxide film and an organomanganese compound adhered inside the processing chamber react therewith without excess and deficiency, and the supply amount of the oxygen containing gas by which the reaction is conducted without excess and deficiency is an amount capable of cutting the n-bonds and exposing Mn.

9. The method of claim 2, wherein a supply amount of the oxygen-containing gas is smaller than or equal to a supply amount of the organomanganese compound.

10. The method of claim 2, wherein a partial pressure of the oxygen-containing gas in processing chamber at the time of supplying the oxygen-containing gas is set in a range from about 1 ppb to about 10 ppm.

11. The method of claim 2, wherein a process recipe completes the film forming process after the supply of the oxygen-containing gas without supplying the gas containing an organomanganese compound.

12. The method of claim 11, wherein, after the completion of the process recipe, Cu or Cu alloy is formed on the manganese oxide film without breaking vacuum or bringing the manganese oxide film into contact with oxygen, water or the air.

13. The method of claim 2, wherein the manganese oxide film is formed by CVD or ALD.

14. A computer-readable storage medium storing a control program for controlling a film forming apparatus, wherein the control program controls, when executed, the film forming apparatus to execute the metal oxide film forming method described in claim 1.

15. A computer-readable storage medium storing a control program for controlling a film forming apparatus, wherein the control program controls, when executed, the film forming apparatus to perform the manganese oxide film forming method described in claim 2.
